(19) United States
(12) Patent Application Publication
(10) Pub. No.: US 2012/0241612 A1
(43) Pub. Date: Sep. 27, 2012

(54) Electron Beam Biprism Device and Electron Beam Device

(75) Inventors: Ken Harada, Fuchu (JP); Akira Sugawara, Yokohama (JP); Noboru Moriya, Tokorozawa (JP)

(73) Assignee: Hitachi Ltd, Chiyoda-ku Tokyo (JP)

(21) Appl. No.: 13/514,654

(22) PCT Filed: Dec. 6, 2010
(86) PCT No.: PCT/JP2010/071826

§ 371 Date: Jun. 8, 2012

(30) Foreign Application Priority Data
Dec. 11, 2009 (JP) 2009 281123

(51) Int. Cl. H01J 37/26; H01J 3/26

(52) U.S. Cl. 250/311; 250/396 R

(57) ABSTRACT

Disclosed are an electron beam biprism device and an electron beam device, in which, in order to implement a fringe scan method in an electron beam interferometer, a deflection function in one direction is added to the function of an electron beam biprism, and electron beams passing the left and right sides of a filament electrode can be respectively deflected at different angles.

### TECHNICAL FIELD

The present invention relates to an electron beam biprism device, an electron microscope in which the electron beam biprism device is used, and an electron beam device.

### BACKGROUND ART

The electron beam has a large interaction with substances and is used various measurements as a probe, such as a structural analysis of a substance by means of electron diffracted image observation, electron micrograph observation, etc. and an element analysis of a substance by electron spectroscopy (energy analysis of an electron beam after transmission of a specimen). The electron beam devices that serve these purposes utilize a characteristic that the electron beam interacts with an electric field and a magnetic field, and use electron lenses for imaging, deflectors for controlling a propagation azimuth of the electron beam, the electron biprisms for splitting the electron beam and making them interfere with each other, etc. These deflectors and electron biprisms can be configured to be of either an electric field type or a magnetic field type. Although a deflection effect to the electron beam is different in each type in that the effect lies in a direction of the electric field in the electric field type whereas it lies in a vertical direction to the magnetic field, the fundamental effect is equivalent. Therefore, although the electron beam device of the electric field type will be explained in this application, it is not limited to the electric field type.

### <Deflector>

FIG. 1 shows a cross section of a deflector including two opposing parallel plate electrodes. The sheet is a plane (deflection plane) perpendicular to the parallel plate electrodes including an optical axis 2 of the electron beam device, and an electric field generated when a voltage is applied to the parallel plate electrodes is in a direction perpendicular to the optical axis 2 (a transverse direction on the sheet). The electron beam incident from the upside on the optical axis receives an electromagnetic force in a direction perpendicular to its propagation direction and its trajectory is deflected. When using a homogeneous field approximation in which disturbance of an electric field at both ends of the parallel plate electrodes is disregarded and the electric field is generated only within a range of the electrodes, a deflection angle S is expressed by a simple relationship shown by Formula 1 of FIG. 16, using a length of the electrodes in an optical axis direction 1, a distance between the opposing electrodes d, an acceleration voltage of the electron beam Vₒ, an applied voltage V_{BD}, and a deflection coefficient K_{BD}. In this application, hereafter, unless otherwise noted, a discussion will be given using the homogeneous field approximation.

Although in the electric field, an electron trajectory 27 draws a parabola, it goes straight after being emitted from the electric field region. As shown in FIG. 1, an imaginary trajectory obtained by extending the trajectory 27 of the electron beam entering along the optical axis 2 and an imaginary trajectory obtaining by making a trajectory of the electron beam after being emitted from the deflector go back along its straight line intersect just in a central part of the parallel plate electrodes. An intersection point of the two imaginary straight trajectories is called a deflection point 83. A plane 835 perpendicular to the optical axis on which a deflection point 83 places is located in the center of the parallel plate electrodes.

The plane on which the deflection point places and that is perpendicular to the optical axis plays an important role in constructing an interference system. Hereafter, unless otherwise noted in this application, let it be assumed for simplicity that the electron trajectory in the deflector is drawn by a straight line and the electron beam is given a predetermined deflection either at the deflection point or in a plane that includes the deflection point and is perpendicular to the optical axis. It is known that this assumption holds without any problem within a range of paraxial approximation that deals with a trajectory of the electron beam in the vicinity of the optical axis.

### <Two-Stage Deflector>

FIG. 2 illustrates two-stage deflectors including two sets of parallel plate electrodes, and the electron trajectory 27 deflected in the deflectors. Since the homogeneous field approximation is used, the electron beam draws a parabolic trajectory in the first deflector on the upstream side, subsequently draws a straight trajectory in the first deflector to the lower second deflector, and draws a parabolic trajectory again in the second deflector.

An imaginary trajectory 29 that goes back on the trajectory of the electron beam emitted from the second deflector while keeping its straight line, as it is, intersects an imaginary trajectory 28 of the incident electron beam along the optical axis 2 in a region where no electric field exists between the first deflector and the second deflector. That is, in the two-stage deflectors, by controlling the deflection angles β₁ and β₂ of the upper and lower deflectors, it is possible to control a deflection point 86 synthesized regardless of existence or absence of the electric field and a position in a plane 865 that includes the deflection point 86 and is perpendicular to the optical axis.

FIG. 3 illustrates the electron trajectory 27 in the case where polarity of the applied voltage of the second deflector is reversed. The figure shows that the deflection point 86 can be controlled not only to be within a range of the deflectors made in two stages, but also to be outside the deflectors and so that a real electron trajectory may intersect the optical axis 2. Although FIG. 3 draws the diagram where the deflection direction of the electron beam is reversed by reversing polarity of the applied voltage to the second deflector, the deflection direction can be controlled by controlling the applied voltage to an electrode opposing to that of FIG. 3.

### <Electron Biprism>

The electron biprism is an electrooptical device indispensable to the interference system as a beam splitter in the electron beam. It has a characteristic of separating an incident electron beam into two electron beams (22, 24) and deflecting the two electron beams to directions in which they approach mutually to the optical axis or to directions in which they separate mutually from the optical axis by the same angle α regardless of a distance from the optical axis 2.

Generally, the electric field type electron biprism is configured to include a filament electrode 9 made of conductive filament and parallel plate grounded electrodes 99 held in a form that sandwiches the electrode. FIG. 4 is a sectional view of the electric field type electron biprism. The sheet is a plane perpendicular to the electron biprism including the optical axis 2 of the electron beam device, and a small circle in the central part shows a cross section of the filament electrode 9. For example, if a positive voltage is applied to the filament electrode 9, the electron beams (22, 24) passing both sides of the filament electrode will be deflected in directions in which they face each other by a potential of the filament electrode by the same angle α. Conversely, if a negative voltage is applied to the filament electrode 9, the two electron beams will be deflected by the same angle in a direction in which they separate from each other. Although as the electron beam leaves the filament electrode 9, a potential acting on the electron beam becomes smaller, since a spatial extent where it acts becomes longer, accordingly the deflection angle of the electron beams is proportional to the applied voltage to the filament electrode 9 regardless of its incident position. That is, with “a” denoting the deflection angle of the electron beam by the electron biprism, the deflection angle has a simple relationship expressed by Formula 2 shown in FIG. 4 using an applied voltage V_{F} to the filament electrode 9 and a deflection coefficient k_{F}.

Since a characteristic that the electron biprism defects the electron beams in directions in which they face each other symmetrically to the optical axis 2 regardless of the eccentric distance from the optical axis 2 or in directions in which they separate from each other by the same angle corresponds to an effect of a biprism that combines two prisms in the optics, it is called an electron biprism. If the electron beams have coherence, interference fringes 8 will be observed in a region where the separated two electron beams (22, 24) superimpose on the downstream side of the electron biprism. An image obtained by making the electron beam having information of an object in the one side of the separated two electron beams interfere with the electron beam in the other side as an electron beam (a reference wave 23) having, for example, an already known phase distribution such as a plane wave is an interferogram (an electron beam hologram) [Nonpatent Literature 2].

Like the electron trajectory 27 shown in the deflector of FIG. 1, the electron trajectories (22, 24) of the electron biprism can also be expressed with the imaginary straight trajectories (28, 29), and a deflection point 85 is located in a plane 855 on which the filament electrode 9 perpendicular to the optical axis is placed.

In this application, when describing “the electron biprism”, it is a general term of the conventional electron biprism including a filament electrode, and the electron biprism having also the deflection function that is considered to be an object of this application is called the “electron beam biprism device” including its deflection mechanism. Moreover, when referring to a strict position in the electron optical system, it is described, for example, as a “position of the filament electrode of the electron biprism.”

### <Fringe Scanning Method>

Since the interferogram by the electron beam includes an image and the interference fringes, techniques of the fringe analysis are usable for its analysis, and phase information extraction methods different from the Fourier transform method in principle (fringe scanning methods (Patent Literature 1) (Nonpatent Literature 3), a Moiré method (Nonpatent Literature 4), etc.) can be used. Especially, the fringe scanning method using multiple images obtained by controlling the phase of the interference fringes utilizing a phase difference of an object wave and a reference wave is a method that can achieve high resolution in a respect that spatial resolution of a reconstruction image does not depend on an interference fringe spacing. Its principle is to record M sheets of interferograms while the phase difference of the object wave and the reference wave is shifted by (2π)/M and obtain a phase distribution φ(x, y) of the object wave based on Formula 3 shown in FIG. 16 designating the m-th intensity distribution of the multiple images by I(x, y, m). Because modulation (sine curve) of the contrast that accompanies the modulation of the phase difference must be decided, there is a limitation that the number of images M should be three or more.

In the case where the basic interference fringes exist in the image like an electron beam interferogram, Formula 3 is modified a little bit to become like Formula 4 shown in FIG. 16. Here, Rₓ is a spatial frequency (carrier-spatial frequency) of the basic interference fringes, and is a notation assuming that the interference fringes are arranged in an X-axis direction. The basic interference fringes are ones that result from the relative angle of the object wave and the reference wave, a phase distribution by the basic interference fringes has a linear inclination in the X-axis direction, and therefore its correction is easy.

FIG. 5 shows a procedure of the fringe scanning method that is performed in the interferogram 88 in which the interference fringes 8 are superimposed on the image of the specimen. FIG. 5(a) is an interferogram of the first sheet, (b) is an interferogram of the second sheet where the phase difference between the object wave and the reference wave is shifted by 2π/3 from the interferogram of (a), and (c) is an interferogram of the third sheet where the relative phase difference is further shifted by 2π/3 from the interferogram of (b) (by 4π/3 from A). An amplitude distribution image and a phase distribution image φ(X, y) can be obtained by performing an image processing on the three interferograms based on Formula 4. Regarding the number of sheets of the interferogram to be used, a minimum number of sheets is three that is exemplified in FIG. 5, and if it is more than or equal to three, there is no dependence on the number of sheets. Since the interferograms (FIGS. 5(b) and (c)) having the interference fringes that fill spaces between the interference fringes and the interference fringes in FIG. 5(a) are used, the spatial resolution by this method does not depend on the interference fringe spacing, which makes it possible to achieve high resolution. However, since observation and recording of the interferogram is performed after controlling the phase difference of the object wave and the reference wave, the phase difference at that time is made to be already known, and then the phase information is extracted, this procedure requires higher degree of work than the Fourier transform method does as the interference microscopy. Therefore, it has not come to spread generally.

Especially, in an electron optical system, the method of controlling the phase difference of the object wave and the reference wave with high precision is not put in practical use, and there is tried no other methods better than the following methods: a method whereby a position of the specimen is moved and the movement of the position is corrected by an image processing after the recording; a method of moving the electron biprism in a direction perpendicular to both the optical axis and the filament electrode (in FIG. 4, the transverse direction of the sheet); a method of varying an incident angle of the electron beam to the specimen in a deflection plane that the electron biprism determines; etc.

### CITATION LIST

### Patent Literatures

Patent Literature 1: International Publication WO 01/75394A1
Patent Literature 2: Japanese Unexamined Patent Publication No. 2005-197165

### Nonpatent Literatures

Nonpatent Literature 1: Katsumi Ura: “Nano electron optics”, KYORITSU SHUPPAN CO., LTD., Chapter 2
Nonpatent Literature 2: A. Tonomura: Electron Holography, 2nd ed. (Springer, Heidelberg. Germany, 1999) Chapter 5.
Nonpatent Literature 3: Q. Ru, J. Endo, T. Tanji, and A. Tonomura: Applied Physics Letters, Vol. 59, (1991) 2372.
Nonpatent Literature 4: Ken Harada, Keiko Ogai, and Ryuichi Shimizu: Journal of Electron Microscopy, Vol. 39 (1990) 470.
Nonpatent Literature 5: Ken Harada, Akira Tonomura, Yoshihiko Togawa, Tetsuya Akashi, and Tsuyoshi Matsuda: Applied Physics Letters, Vol. 84, (2004) 3229

### SUMMARY OF INVENTION

### Technical Problem

In the conventional electron beam interference method, the electron biprism was placed on the optical axis and in a plane perpendicular to the optical-axis. For example, in the electric field type, the electron beams passing by the both sides of the filament electrode were deflected symmetrically to the optical axis in directions in which they faced each other or in directions in which they separated from each other, the two electron beams were superimposed on the downstream side of the electron biprism, and the interferogram was measured. Although this method was a simple method, the resolution of the phase image reproduced from an interferogram was three times as large as the recorded interference fringe spacing, and there was a theoretic restriction that the resolution remained at low spatial resolution.

One of measurement methods that are free from this restriction is a fringe scanning method. This is an interference measurement method whereby the phase difference is given between the object wave and the reference wave, and a phase image is made to reflect a spatial resolution of a recording system, as it is, from plural sheets (at least three sheets) of the interferograms such that only interference fringes superimposed on the specimen image are modulated by an arithmetic processing. The fringe scanning methods having been tried up to now include, for example, (1) a method whereby the position of the specimen is moved and the movement of position is corrected by an image processing after the recording, (2) a method whereby the electron biprism is moved in a direction perpendicular to the both the optical axis and the filament electrode, (3) a method whereby an incident angle of the electron beam to the specimen is changed, etc. However, these techniques had problems that real-timeness was lacking, an analysis processing after image recording became complicated, or accuracy sufficient for modulation of the phase difference was not achieved. Furthermore, when the methods of the above-mentioned (1) to (3) are performed in the conventional electron beam interferometer, since the Fresnel fringes superimposed on the interferogram are also modulated at the same time and generate a new artifact, the fact is that an accuracy expected from a principle of the fringe scanning method has not been achieved.

### Solution to Problem

The present invention is made to provide an electron biprism for realizing a suitable fringe scanning method in the electron biprism interferometer, and is one that makes it possible to deflect the electron beams passing by right- and left-hand sides of the filament electrode by mutually different angles by adding a function of deflecting them to one direction to functions of the electron biprism. Its concrete structure is the electron biprism to which two-stage deflectors on the optical axis are added, and is characterized in that the electron beams are controlled so that the deflection points by the deflectors may be positioned in a plane on which the filament electrode is placed regardless of spatial locations of the deflectors by controlling magnitudes and directions of the deflection angles of the two-stage deflectors.

When performing the fringe scanning method in a double-biprism electron interference system, it is considered that an optical system of imaging a specimen image at its filament electrode position using the electron beam biprism device according to this application as an upper-stage electron biprism is most suitable. Since both of the plane including the deflection point by the electron biprism and the plane including the deflection point by the deflectors are in agreement with the image plane position, even if the electron beam is deflected, a position of the specimen image does not move on an observation and recording plane, which enables the fringe scanning method to be performed effectively.

### Effect of Invention

According to this application, the electron beams passing by right- and left-hand both sides of the filament electrodes are given deflection in one direction in addition to a deflection symmetrical to the optical axis and, as a result, it becomes possible to give the right- and left-hand electron beams emitted from the electron beam biprism device mutually different deflection angles. Therefore, in the image plane of a specimen on the downstream side of the electron beam biprism device, a control of a phase difference of an object wave and a reference wave becomes possible. That is, a relative spatial relationship of the image of the specimen recorded as an interferogram and interference fringes superimposed on the image can be modulated with high precision without changing the image of the specimen and its position, so that the fringe scanning method becomes implementable.

### BRIEF DESCRIPTION OF DRAWINGS

FIG. 1 is a schematic diagram showing an electric field type deflector and deflection of an electron beam by the deflector.

FIG. 2 is a schematic diagram showing electric field type deflectors made in two stages and deflection of the electron beam by the deflectors.

FIG. 3 is a schematic diagram showing deflection that is by an electric field type deflector configured to be two stages and the deflector and is different from FIG. 2.

FIG. 4 is a schematic diagram showing an electron biprism, and deflection of the electron beam by the electron biprism.

FIG. 5(a) is a diagram showing the first sheet of the interferogram, FIG. 5(b) is a diagram showing the second sheet of the interferogram whose phase of an interference fringe is shifted from (a) by 2π/3, and

FIG. 5(c) is a diagram showing the third sheet of the interferogram whose phase of the interference fringe is shifted from (b) by 2π/3 (whose phase is shifted from (a) by 4π/3).

FIG. 6 is a schematic diagram showing a configuration of the electron beam biprism device according to a first embodiment of the present invention, and deflection of the electron beam.

FIG. 7(a) is a schematic diagram showing a relationship among a source, a light ray, and the interference fringes when the conventional electron biprism is replaced with an optical biprism.

FIG. 7(b) is a schematic diagram showing a relationship among a source, a light ray, and the interference fringes when the electron biprism according to the first embodiment is replaced with a corresponding optical biprism.

FIG. 8 is a schematic diagram showing a whole picture of an appearance of the electron beam biprism device according to the first embodiment of the present invention.

FIG. 9(a) is a diagram showing the electron beam biprism device comprised of the electron beam biprism device, the first deflector, and the second deflector in this order from the upstream side of the electron beam in the travelling direction, FIG. 9(b) is a diagram showing the electron beam biprism device comprised of the first deflector, the electron beam biprism device, and the second deflector in this order from the upstream side of the electron beam in the travelling direction, and FIG. 9(c) is a diagram showing the electron beam biprism device comprised of the first deflector, the second deflector, and the electron beam biprism device in this order from the upstream side of the electron beam in the travelling direction.

FIG. 10 is a schematic diagram showing an electron beam interference system according to a second embodiment of the present invention.

FIG. 11 is a schematic diagram showing a whole picture of a system of an electron beam interference microscope of the present invention.

FIG. 12 is a schematic diagram showing an electron beam interference system according to a third embodiment of the present invention.

FIG. 13 is a schematic diagram showing an electron beam interference system according to a fourth embodiment of the present invention.

FIG. 14 is a schematic diagram showing an electron beam interference system according to a fifth embodiment of the present invention.

FIG. 15 is a schematic diagram showing an electron beam interference system according to a sixth embodiment of the present invention.

FIG. 16 is an explanatory drawing showing expressions.

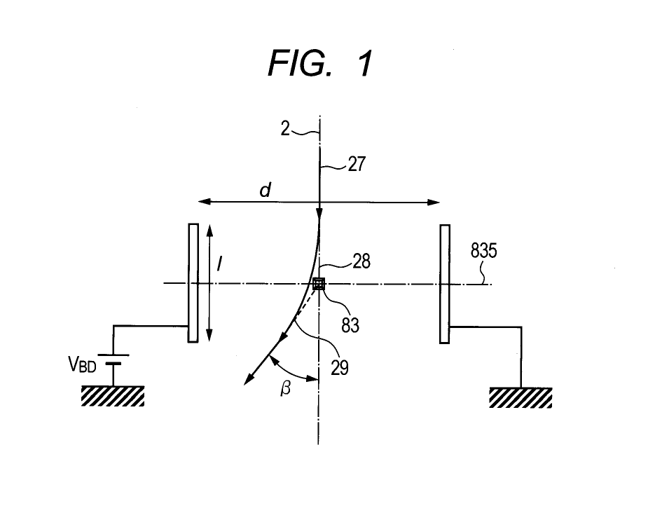

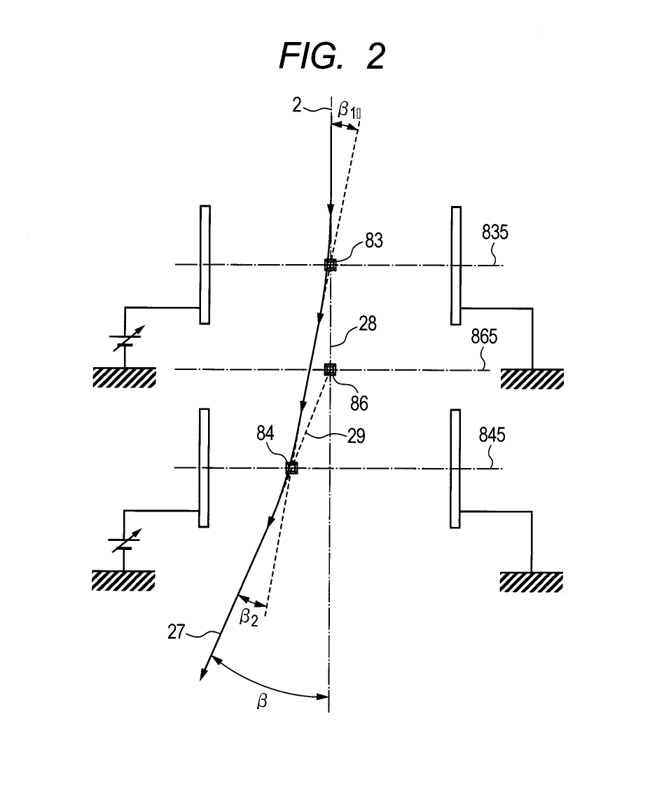

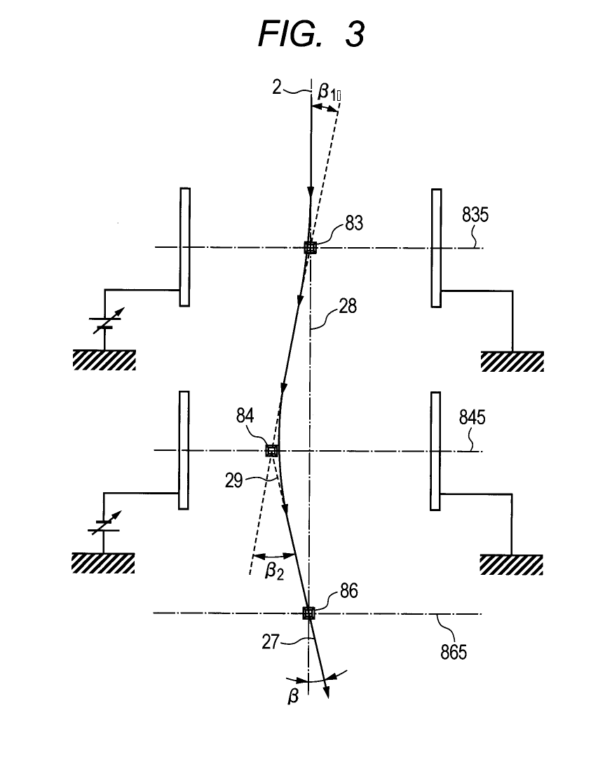

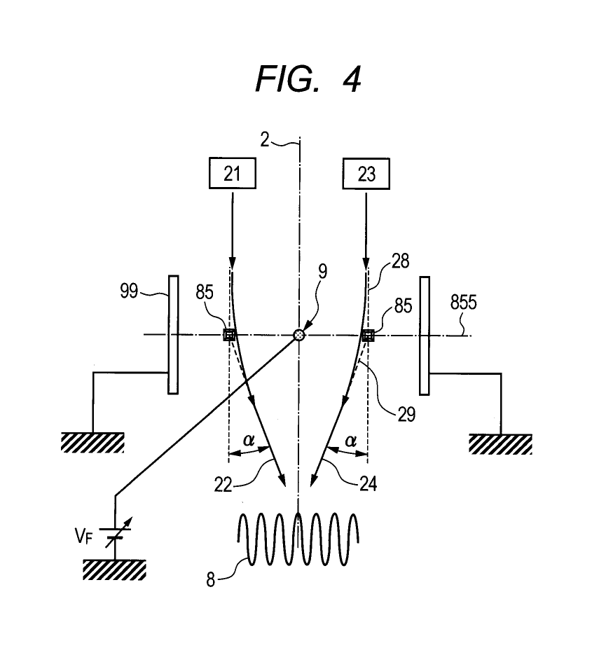

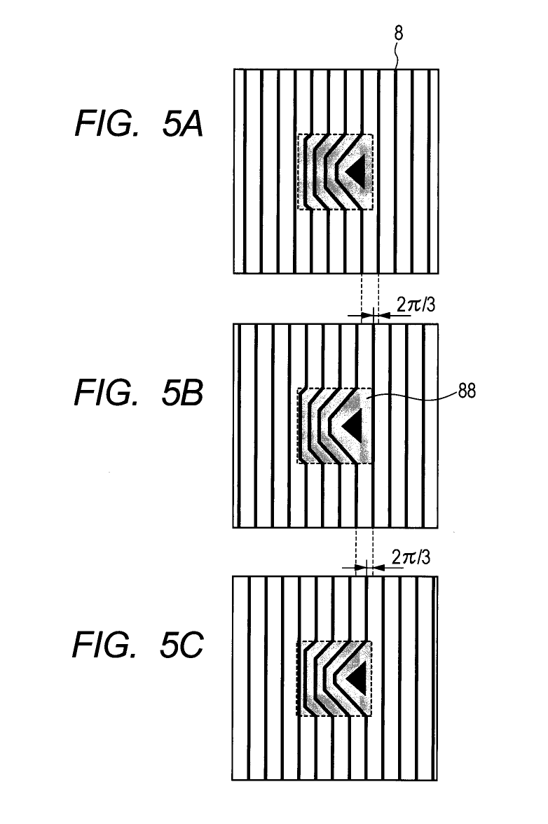

### PREFERRED EMBODIMENTS

### First Embodiment

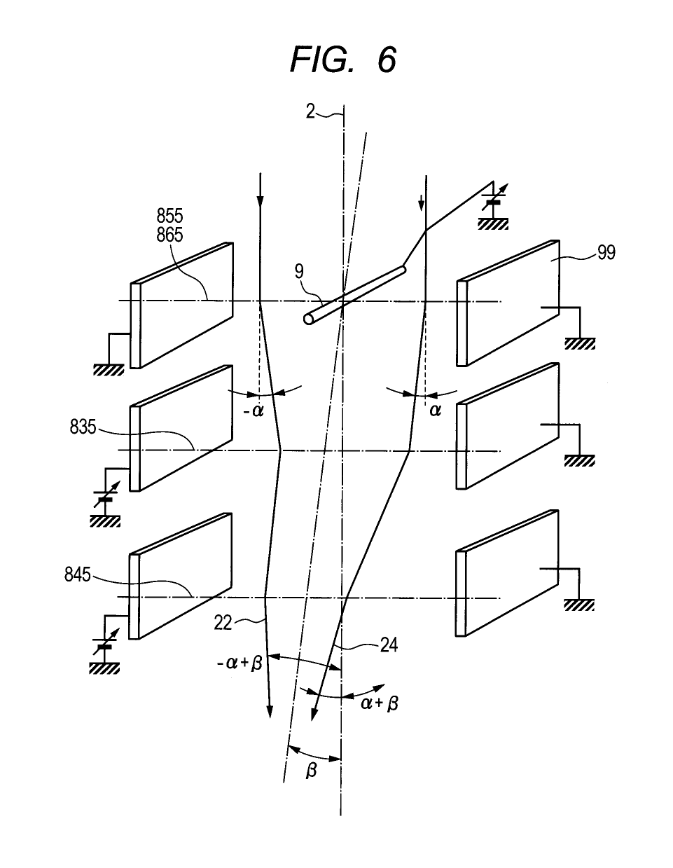

Hereafter, one example of an electron beam biprism device in the present invention will be described in accordance with specific examples. FIG. 6 schematically shows a mechanism of the electron beam biprism device. The electron biprism is placed in the highest stage, and the deflectors comprised of two stages are arranged on the downstream side of the electron beam in the travelling direction. For example, let it be assumed that two electron beams (22, 24) that are split by the electron biprism and are deflected in directions in which they face each other symmetrically to an optical axis 2 by an angle α have a deflection point 86 in a plane 855 including the filament electrode 9 of the electron biprism (the plane 855 that includes a deflection point 85 of the electron biprism and is perpendicular to the optical axis), and receive deflections by an angle S finally.

At this time, with a downward direction (a travelling direction of the electron beam) of the optical axis being taken as a z-axis, and a clockwise direction to the travelling direction being defined as a positive direction of angle, the electron beam 22 on the left-hand side on the sheet of FIG. 6 is subjected to a deflection of −α by the electron biprism and a deflection of +β by two-stage deflectors, and thereby an angle of the electron beam emitted from the electron beam biprism device to the optical axis 2 becomes −α+β. Similarly, the electron beam 24 on the right-hand side on the sheet is subjected to a deflection of +α by the electron biprism and a deflection of +β by the two-stage deflectors, and thereby an angle of the electron beam emitted from the electron beam biprism device to the optical axis 2 becomes +α+β.

Consequently, an angle difference of the two electron beams (22, 24) is 2α, which does not change from that after passing through a filament electrode 9 of the electron biprism. However, the two electron beams (22, 24) after being emitted from the electron beam biprism device are inclined to one direction by an angle β, becoming asymmetrical to the optical axis 2.

Only when the plane 855 that includes the deflection point 85 of the upstream side electron biprism and is perpendicular to the optical axis and a plane 865 that includes the deflection point 86 of the two-stage deflectors on the downstream side and is perpendicular to the optical axis coincide with each other, it becomes possible to describe a relation of the two deflection angles α and β by a simple relation like this. That is, a control of the position in the plane 865 that includes the deflection point 86 by the two-stage deflectors on the downstream side and is perpendicular to the optical axis is important for a control of a phase difference of the two electron beams (22, 24).

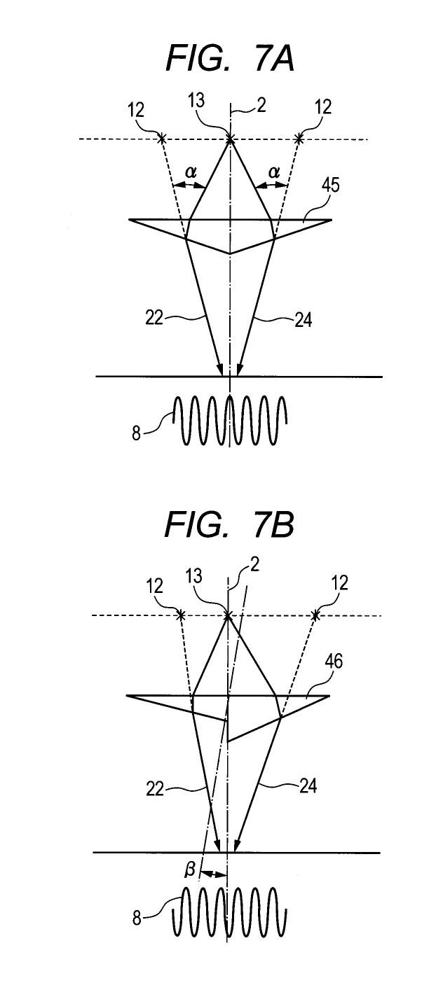

FIG. 7 shows an example of a case where the deflection angles of the right- and left-hand electron beams (22, 24) become asymmetrical to the optical axis 2 with a replacement of an optical biprism. FIG. 7(a) shows a Fresnel biprism 45 corresponding to the conventional electron biprism and a situation of deflection thereby.

The light rays (22, 24) emitted from a real image 11 of the source are deflected in directions in which they face the optical axis 2 mutually by the biprism 45 placed in the propagation path on the optical axis 2. Consequently, these are equivalent to two light rays (22, 24) emitted from two virtual sources 12 and are made to superimpose on the downstream side of the biprism 45, generating interference fringes 8.

FIG. 7(b) shows a biprism 46 corresponding to the electron beam biprism device according to this application and a situation of deflection thereby. Because angles of side parts of the biprism 46 are different between the right and the left, the deflection angles of right- and left-hand light rays are different. Therefore, positions of the virtual sources 12 become asymmetrical to the optical axis 2 and, as a result, the phase difference of right- and left-hand light rays (22, 24) makes fringe positions of the interference fringes 8 vary.

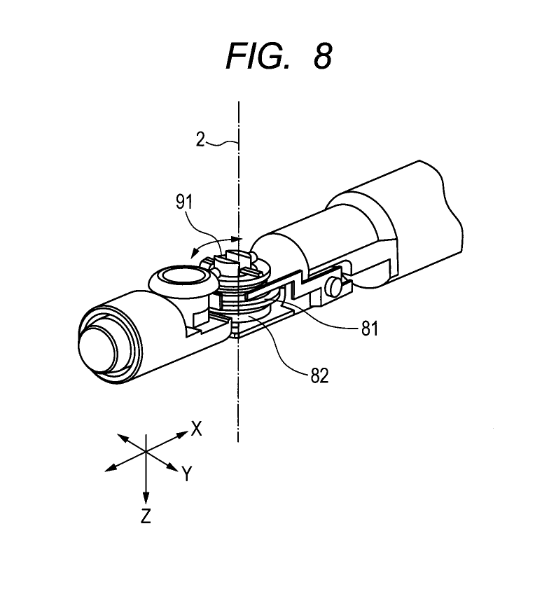

FIG. 8 shows one example of an appearance of the electron beam biprism device in this application. This has a mechanism such that two-stage deflectors (81, 82) are incorporated in a mechanism of the conventional electron biprism in addition to an electron biprism 91 on its downstream side. For this reason, the electron biprism 91 and the two-stage deflectors (81, 82) can make, as one body, a slight movement in two directions (X- and Y-axis directions) in a plane perpendicular to the optical axis 2 of the electron beam device, a rotation of an azimuth about an axis parallel to the optical axis that is set to a rotation axis, attachment of the mechanism into and detachment thereof from a path of the electron beam. It is necessary to make the deflection plane including the optical axis 2 by the electron biprism 91 coincide with the deflection plane including respective optical axes 2 of the two-stage deflectors (81, 82), and this can be achieved by mechanical precision.

Then, configurations of the electron biprism and the two-stage deflectors will be explained below.

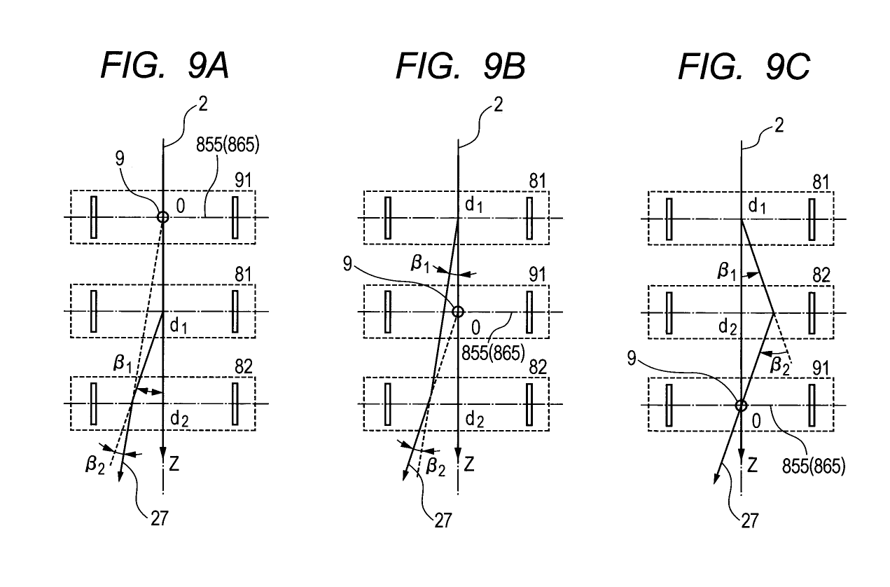

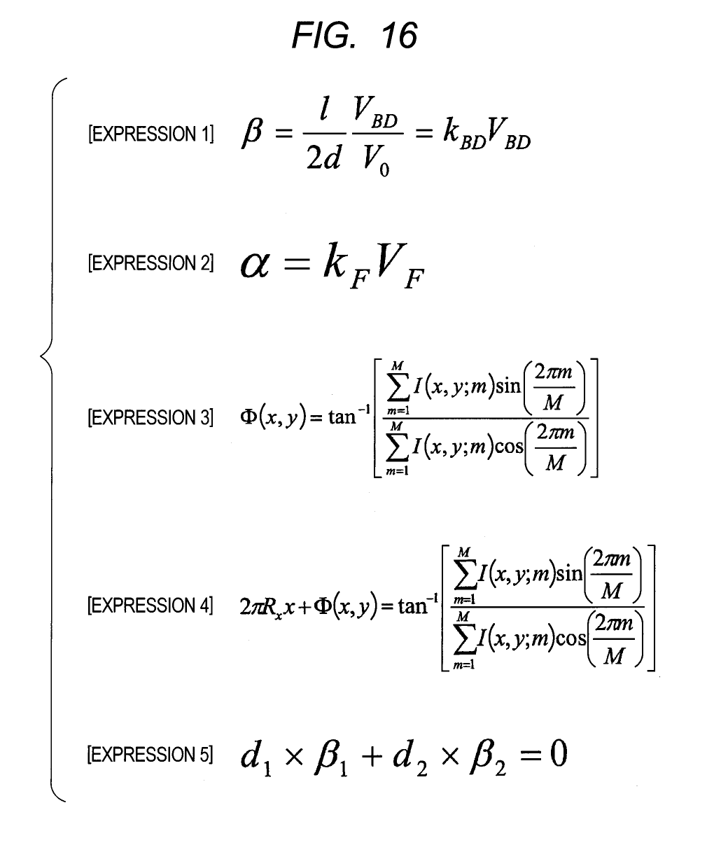

The electron beam biprism device of this example has a triple configuration comprised of the electron biprism 91 and the deflectors (81, 82) made in two stages. Therefore, three ways of configurations shown in FIG. 9 become possible as a sequence of arranging them in an optical axis direction. That is, FIG. 9(a) shows the same configuration as that of FIG. 6, and is a triple configuration of the electron biprism 91, the first deflector 81, and the second deflector 82 sequentially from the upstream side of the electron beam in a travelling direction. FIG. 9(b) is a triple configuration of the first deflector 81, the electron biprism 91, and the second deflector 82 in this order in which orders of the electron biprism 91 and the first deflector 81 are interchanged. FIG. 9(c) shows the configuration that the electron biprism 91 is located on the most downstream side, having a triple configuration that includes the first deflector 81, the second deflector 82, and the electron biprism 91 in this order. In any configuration, with a downward direction of the optical axis (a travelling direction of the electron beam) being taken as a Z-axis, the original being made to coincide with the filament electrode 9 of the electron biprism, and the clockwise direction to the travelling direction being defined as a positive direction of the angle, a condition under which the plane 855 that includes the deflection point 85 by the electron biprism 91 and is perpendicular to the optical axis is made to coincide with the plane 865 that includes the deflection point 86 synthesized by the two-stage deflectors (81, 82) and is perpendicular to the optical axis will be able to be expressed by a relational expression like Formula 5 shown in FIG. 16 using the deflection angles of the two-stage deflectors (81, 82) and the positions of the deflectors.

Here, d₁ is a Z-coordinate value of the deflection point by the first deflector 81 when being seen from the Z-coordinate origin, d₂ is a Z-coordinate value of the deflection point by the second deflector 82 when being seen from the Z-coordinate origin, β₁ is a deflection angle by the first deflector 81, and β₂ is a deflection angle by the second deflector 82. According to the definition, the variables take positive or negative values, respectively.

When controlling respective deflection angles of the two-stage deflectors (81, 82) based on Formula 5, the plane 865 that includes the synthesized deflection point 86 by the two-stage deflectors (81, 82) and is perpendicular to the optical axis always coincides with a plane perpendicular to the Z-coordinate origin. A synthesized deflection angle S by the two-stage deflectors (81, 82) at this time is β₁+β₂ (=β).

As is clear on comparing FIG. 9(a), (b), and (c), in FIG. 9(b), the deflection angles by the first deflector 81 and the second deflector 82 are mutually in the same direction, whereas the deflection angles by the first deflector 81 and the second deflector 82 are mutually in opposite directions in configurations of FIG. 9(a) and FIG. 9(c). That is, from a viewpoint of a withstand voltage characteristic of the electron beam biprism device, the configuration of FIG. 9(b) is advantageous.

Although the deflection angle of each deflector can be altered based on Formula 5 at the time of an experiment, on the other hand, distances among the deflectors and the biprism, electrode sizes of the deflectors, etc. are constants decided at the time of design of the mechanism. That is, as is clear from Formula 5, since the deflection angle S and an applied voltage V_{BD} to the deflector are in a proportional relationship, what is necessary is just to control the applied voltages so that a ratio of the applied voltage to the first deflector 81 and the applied voltage to the second deflector 82 may become a predetermined constant value. Incidentally, the deflection angle S by these two-stage deflectors (81, 82) and the deflection angle α by the electron biprism 91 are independent.

### Second Embodiment

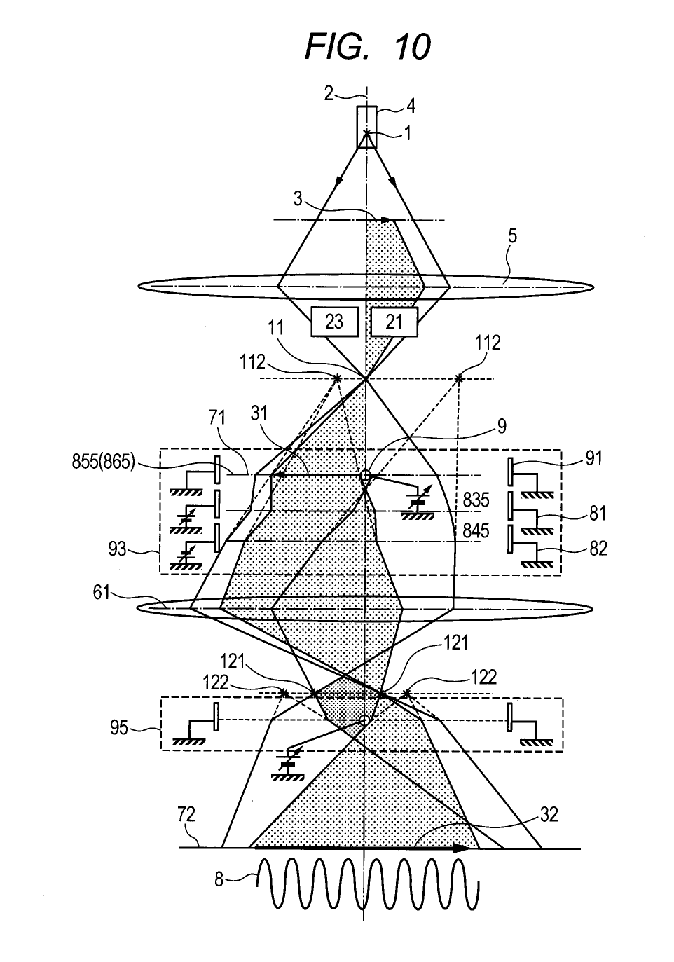

Then, one example of a configuration of the fringe scanning method in the two-stage electron biprism interferometer will be described below. FIG. 10 is a configuration example of an optical system for performing the fringe scanning method in the two-stage electron biprism interferometer using an electron beam biprism device 93. The electron beam biprism device 93 uses a mechanism of a triple configuration comprised of the electron biprism 91, the first deflector 81, and the second deflector 82 from the upstream side shown in FIG. 9(a).

In the two-stage electron biprism interferometer, the electron beam biprism device 93 is used as an upper-stage electron biprism, and an image plane 71 of a specimen is configured to coincide with the plane 855 perpendicular to the optical axis including the position of the filament electrode of the electron biprism 91, namely the deflection point 85 by the electron biprism 91. As a result, the specimen image plane 71, the plane 855 that includes the deflection point 85 by the electron biprism 91 and is perpendicular to the optical axis, and the plane 865 that includes the deflection point 86 by the two-stage deflectors and is perpendicular to the optical axis are configured to be in the same plane where all the planes electrooptically coincide with one another. This means in a design that the image plane 71 can be fitted into the plane 855 that is defined mechanically, includes the deflection point 85 by the electron biprism, and is perpendicular to the optical axis using an objective lens 5, and the plane 865 that includes the deflection point 86 by the two-stage deflectors (81, 82) and is perpendicular to the optical axis can be fitted into the fitted plane through adjustment of the deflection angles by the first deflector 81 and the second deflector 82 in an independent manner, respectively.

In performing the fringe scanning method, the following procedure will be taken: (1) An interference fringe spacing and an interference width of the interferogram (8 and 32) are decided by the upper-stage electron biprism (the electron biprism 91 inside the electron beam biprism device 93 of this application) and a lower-stage electron biprism 95; and subsequently, (2) the fringe positions of the interference fringes 8 are modulated by controlling the phase difference of two electron waves (21, 23) with the two-stage deflectors (81, 82) by this application. That is, since the imaging of a specimen 3 by the objective lens 5 and a modulation operation of the deflection angle by the two-stage deflectors (81, 82) after the deflection for interference by the upper-stage electron biprism 91 was done are performed in this order, the configuration with an order of the electron biprism 91, the first deflector 81, and the second deflector 82 is the most suitable configuration for the fringe scanning method.

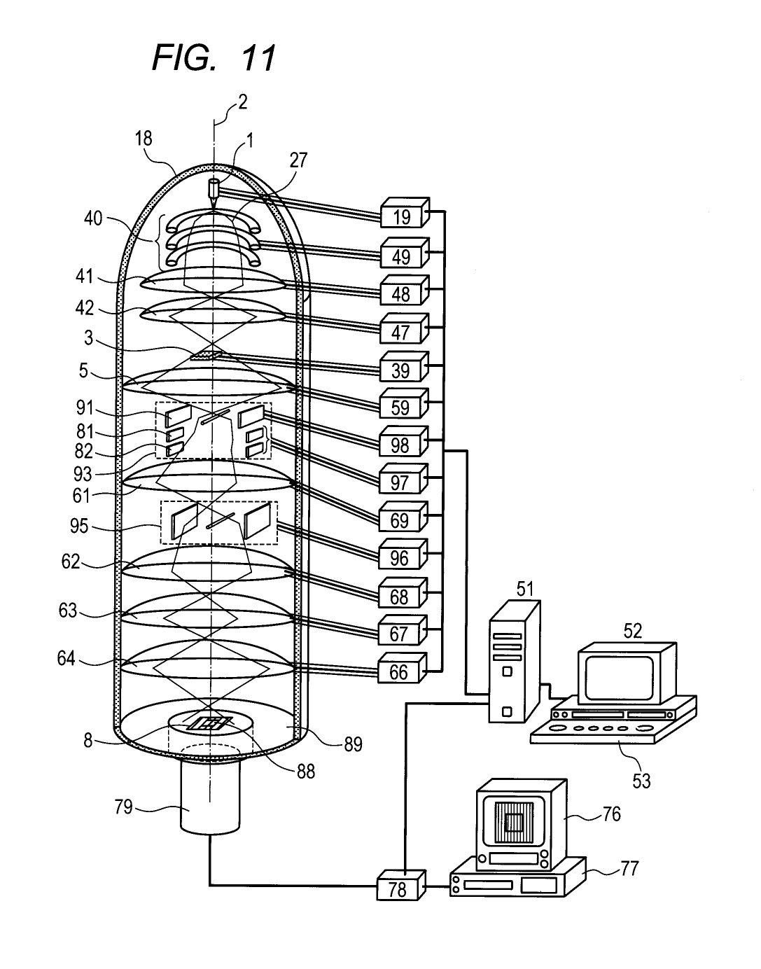

FIG. 11 schematically shows a configuration of an electron microscope system on which the electron beam biprism device 93 of this application is mounted as the upper-stage electron biprism. That is, the electron beam biprism device 93 on the downstream side of the objective lens 5 has a one-body mechanism that includes the first electron biprism 91 and the two-stage deflectors (81, 82) on its downstream side, and the second electron biprism 95 is arranged on their downstream side posterior to the first imaging lens 61.

Regarding the interferogram 88 whose interference fringe spacing and interference width have been decided by the first and second electron biprisms (91, 95), the phase difference of the two electron waves is controlled by a deflection action of the two-stage deflectors (81, 82) and the fringe positions of the interference fringes 8 are modulated. The interferogram 88 of the specimen decided to be under predetermined interference conditions is controlled to be in a predetermined magnification through first, second, third, and fourth imaging lenses (61, 62, 63, and 64), and is recorded in an image observation and recording medium 79 (for example, a TV camera and a CCD camera) on an observation recording plane 89.

Then, it is reproduced as an amplitude image, a phase image, etc. by an arithmetic processing unit 77 and is displayed, for example, on a monitor 76 etc.

Although FIG. 11 is drawn supposing the electron microscope with an acceleration voltage of 100 kV to 300 kV, components of the electron microscope optical system in FIG. 11 are not restricted to those in this figure. Furthermore, in the actual beam device, there exist a beam deflection system that is for changing a travelling direction of the electron beam and is different from this application, an aperture mechanism for limiting a transmission region of the electron beam, etc. in addition to the components shown in this FIG. 11. However, these components are omitted in this figure because they do not have direct relationships to the present invention. Furthermore, although the electron optical system is assembled inside a vacuum chamber 18, which is continuously evacuated by a vacuum pump, a vacuum evacuation system is omitted because it has no direct relationship with the present invention.

### Third Embodiment

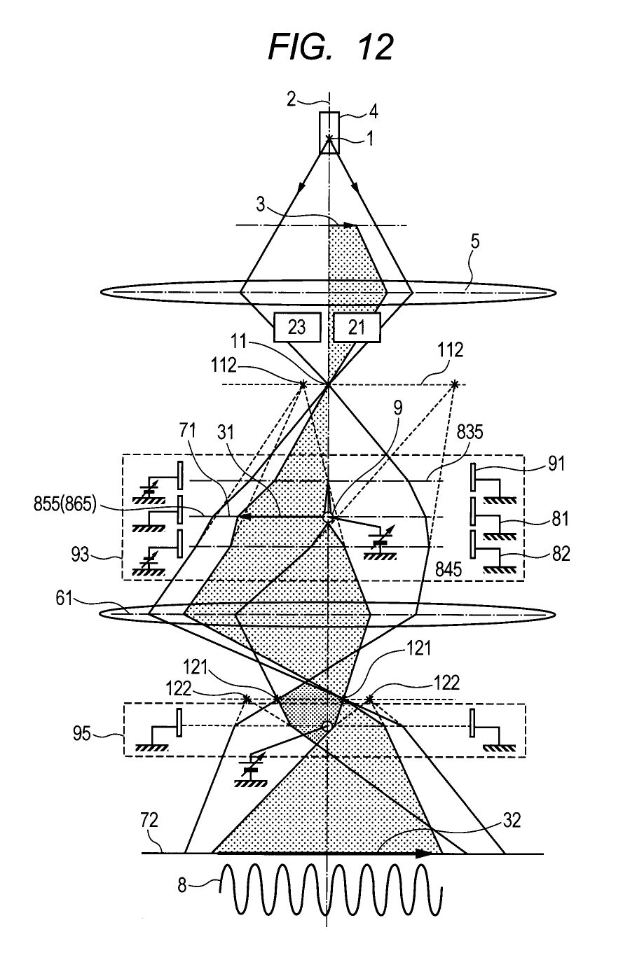

Next, another example of the configuration of the fringe scanning method in the two-stage electron biprism interferometer will be described below. FIG. 12 is a second configuration example of an optical system for performing the fringe scanning method in the two-stage electron biprism interferometer using the electron beam biprism device 93.

The electron beam biprism device 93 uses a mechanism of a triple configuration comprised of the first deflector 81, the electron biprism 91, and the second deflector 82 from the upstream side shown in FIG. 9(b). The two-stage electron biprism interferometer uses the electron beam biprism device 93 as the upper-stage electron biprism, and is constructed so that the image plane 71 of the specimen may coincide with the plane 855 perpendicular to the optical axis including the filament electrode position of the electron biprism 91, i.e., the deflection point 85 by the electron biprism.

A respect that the specimen image plane 71, the plane 855 that includes the deflection point 85 by the electron biprism and is perpendicular to the optical axis, and the plane 865 that includes the deflection point 86 by the two-stage deflectors and is perpendicular to the optical axis are configured to be in an electrooptically coinciding plane is the same as that of the configuration example of the second embodiment. Therefore, the image plane 71 is made to fit to the plane 855 that includes the deflection point 85 by the electron biprism defined mechanically and is perpendicular to the optical axis using the objective lens 71, and regarding the plane 865 that includes the deflection point 86 by the two-stage deflectors (81, 82) and is perpendicular to the optical axis, the fitting is achieved each independently by adjustment of the deflection angles by the first deflector 81 and the second deflector 82, which are made to be the same as the above.

As was explained in FIG. 9, the deflection angles by the first and second deflectors are in the same direction, respectively, in this second configuration example, and this configuration is most advantageous from a viewpoint of the withstand voltage characteristic of the deflector. Since a situation of how it is mounted on the electron microscope is the same as FIG. 11 of the second embodiment, its explanation is omitted.

### Fourth Embodiment

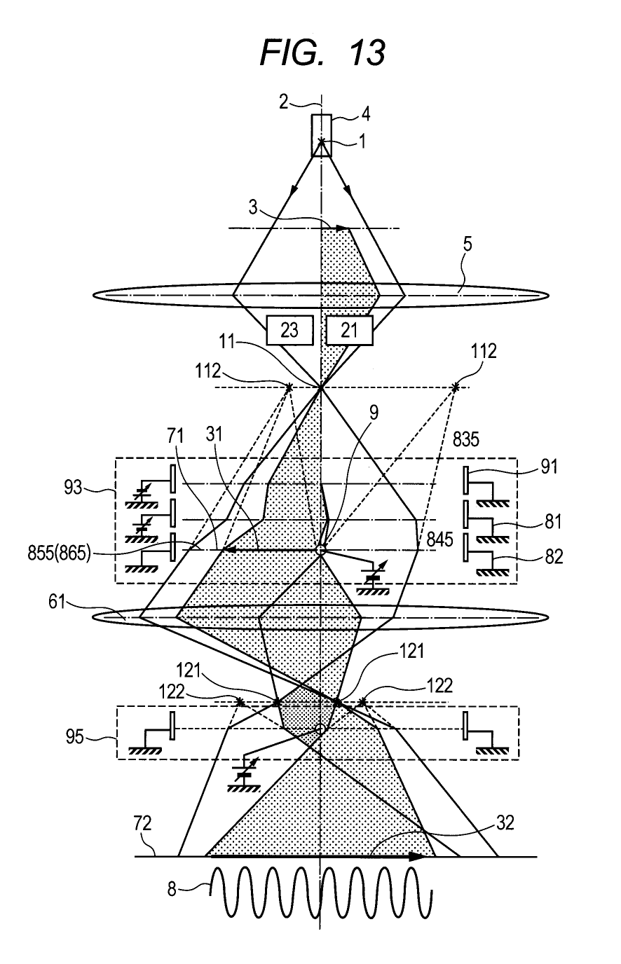

Next, another example of a configuration of the fringe scanning method in the two-stage electron biprism interferometer will be described below. FIG. 13 is a third configuration example of an optical system for performing the fringe scanning method in the two-stage electron biprism interferometer using the electron beam biprism device 93. The electron beam biprism device 93 uses a mechanism of a triple configuration comprised of the first deflector 81, the second deflector 82, and the electron biprism 91 from the upstream side shown in FIG. 9(c).

In the two-stage electron biprism interferometer, the electron beam biprism device 93 is used as the upper-stage electron biprism, and the image plane 71 of the specimen is constructed so as to coincide with the plane 855 that includes the filament electrode position of the electron biprism 91, i.e., the deflection point 85 by the electron biprism 91 and is perpendicular to the optical axis. A respect that the specimen image plane 71, the plane 855 that includes the deflection point 85 by the electron biprism 91 and is perpendicular to the optical axis, and the plane 865 that includes the deflection point 86 by the two-stage deflectors and is perpendicular to the optical axis are configured to be in an electrooptically coinciding plane is the same as those of the second and third embodiments.

In addition, a respect that the image plane 71 can be made to fit to the plane 855 that includes the deflection point 85 by the electron biprism defined mechanically and is perpendicular to the optical axis using the objective lens 5, a respect that fitting can be performed to the plane 865 that includes the deflection point 86 by the two-stage deflectors and is perpendicular to the optical axis by adjustment of the deflection angles by the first and second deflectors (81, 82) each independently, and other respects are the same as those of the configuration examples in the second and third embodiments.

For example, in the case of the device having the one-body mechanism explained in FIG. 8, this configuration can be realized immediately by installing the device in an upside down manner.

Since the image plane 71 of the specimen is located on the most downstream side as compared with the second embodiment and the third embodiment, it is possible to make a magnification ratio of the specimen image 31 by the objective lens 5 larger than that of the first configuration example in the third embodiment and that of the second configuration example in the fourth embodiment. Moreover, it is possible for this configuration to obtain the interferograms (8 and 32) having the narrowest fringe spacing among the above-mentioned three configuration examples. A situation of how it is mounted on the electron microscope is the same as FIG. 11 of the third embodiment, its explanation is omitted.

### Fifth Embodiment

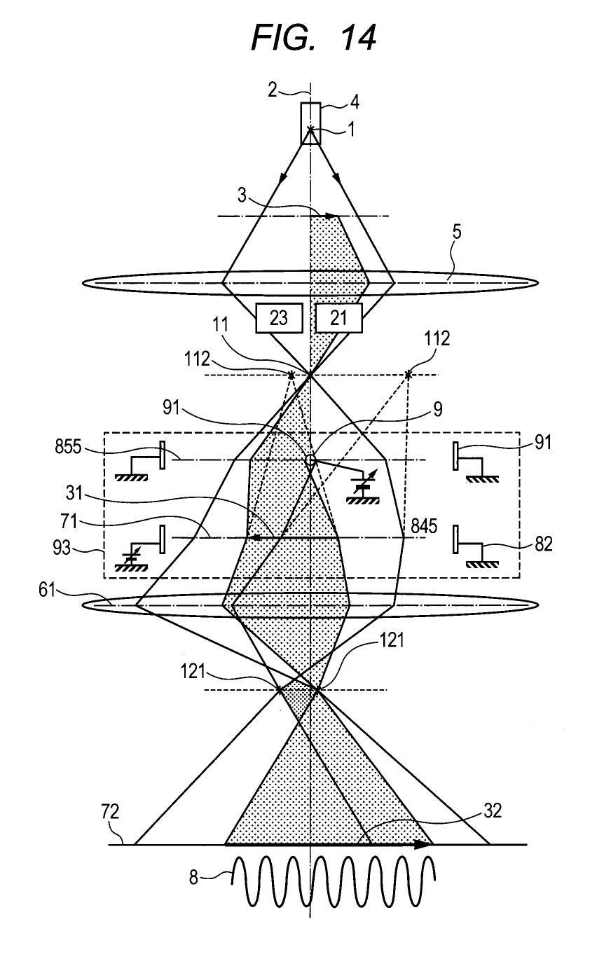

FIG. 14 is a configuration example for performing the fringe scanning method in the conventional interferometer using the electron beam biprism device 93 (only one electron biprism is used). In the example, only the electron beam biprism device 93 in this application is used as the electron biprism, and only one-stage deflector in this application is also used. In FIG. 14, the configuration of FIG. 9(a) is assumed, and a configuration where the deflection angle β₁ of the first deflector 81 in this application is set to zero, that is, a configuration where no voltage is applied to the parallel plate electrodes of the first deflector 81 is assumed. The electron biprism 91 of the electron beam biprism device 93 in this application is placed between the objective lens 5 and the image plane 71 of the specimen and its optical system is constructed so that a plane 845 that includes a deflection point 84 of the second deflector and is perpendicular to the optical axis may coincide with the image plane 71 of the specimen. It is of a configuration that the two electron waves, the object wave 21 and the reference wave 23 that are included in the interferograms (8 and 31) defined by the electron biprism, are deflected by the second deflector 82. Since this deflection is deflection that is given at the image plane position 71 of the specimen, a position of the specimen image 31 does not change but only the phase difference of the two electron waves, the object wave 21 and the reference wave 23, is modulated. That is, the fringe scanning method is possible. However, since this optical system is a conventional interference system, a control of the interference fringe spacing and the interference width that is an advantage of the two-stage electron biprism interferometer and elimination of superimposition of the Fresnel fringes on the interferogram, etc. are unrealizable.

Incidentally, although it was decided that the second deflector on the downstream side of the two-stage deflectors was used in this configuration example, even with a plane 835 perpendicular to the optical axis including a deflection point 83 by the first deflector 81 or with the plane 865 that includes the deflection point 86 and is perpendicular to the optical axis synthesized by the first and second deflectors, if it is made to coincide with the image plane 71 of the specimen, the same effect will be obtained.

### Sixth Embodiment

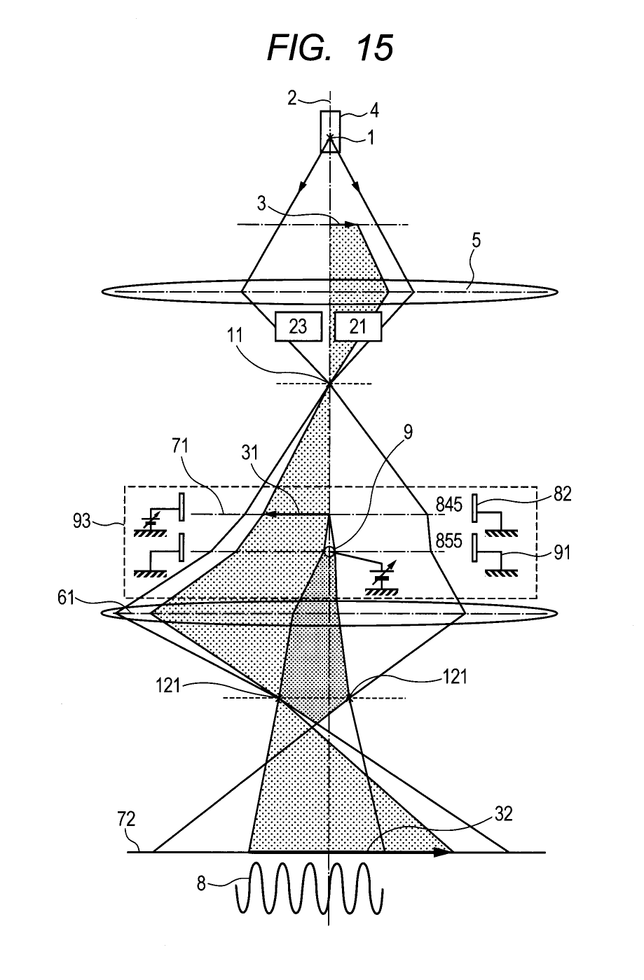

FIG. 15 is a second configuration example for performing the fringe scanning method in the conventional interferometer using the electron beam biprism device 93 according to this application (only one electron biprism is used).

A respect that only the electron beam biprism device 93 in this application is used as the electron biprism and a respect that only one-stage of the deflector in this application is also used are the same as those of the first configuration example in the fifth embodiment. FIG. 15 assumes the configuration of FIG. 9(c). Moreover, it is assumed that the deflection angle β₁ is equal to zero, that is, no voltage is applied to the parallel plate electrodes of the first deflector 81. The electron biprism 91 of the electron beam biprism device 93 in this application is placed between the image plane 71 of the specimen by the objective lens 5 and the first imaging lens 61, and its optical system is constructed so that the plane 845 that includes the deflection point 84 of the second deflector 82 and is perpendicular to the optical axis may coincide with the image plane 71 of the specimen.

Here, since the position of the electron biprism 91 is between the specimen image 31 and the imaging lens 61, the voltage applied to the filament electrode 9 in order to produce interference is a negative voltage, and the polarity of the applied voltage is different from that of the optical system in the sixth embodiment. However, this is not an essential difference. The electron biprism has a configuration where the propagation directions of the object wave 21 and the reference wave 23 that have not yet generated interference are deflected by the second deflector 82 located on the image plane of the specimen 3. Since this deflection is deflection that is given at the image plane position of the specimen, the positions of the specimen images 31 and 32 do not change fundamentally, and only the phase difference of the two electron beams of the object wave 21 and the reference wave 23 is altered after passing through the imaging lens 61.

That is, the fringe scanning method is possible. However, since this optical system is a conventional interference system, a control of the interference fringe spacing and the interference width that is an advantage of the two-stage electron biprism interferometer and elimination of superimposition of the Fresnel fringes on the interferogram, etc. are unrealizable. Incidentally, although it was decided that the second deflector 82 on the downstream side of the two-stage deflectors was used in this configuration example, even with the plane 835 that includes the deflection point 83 by the first deflector and is perpendicular to the optical axis or the plane 865 that includes the synthesized deflection point 86 by the first and second deflectors and is perpendicular to the optical axis, if it is made to coincide with the image plane 71, the same effect will be obtained. These respects are the same as those of the fifth embodiment.

### REFERENCE SIGNS LIST

1 Electron source or electron gun,
11 Real image of electron source under objective lens,
12 Virtual image of electron source,
112 Virtual image of electron source under objective lens,
121 Real image of electron source under first magnifying lens,
122 Virtual image of electron source under first magnifying lens,
13 Real image of source,
18 Vacuum chamber,
19 Control unit of electron source,
2 Optical axis,
21 Object wave,
22 Trajectory of electron beam corresponding to object wave,
23 Reference wave,
24 Trajectory of electron beam corresponding to reference wave,
27 Trajectory of electron beam,
28 Imaginary trajectory of incident electron beam,
29 Imaginary trajectory of electron beam after deflection,
3 Specimen,
31 Image of specimen imaged by objective lens,
32 Image of specimen imaged by first imaging lens,
39 Control unit of specimen,
40 Acceleration tube,
41 First condenser lens,
42 Second condenser lens,
45 Optical biprism,
46 Optical biprism for realizing right-left asymmetrical deflection,
47 Control unit of second condenser lens,
48 Control unit of first condenser lens,
49 Control unit of acceleration tube,
5 Objective lens
51 Control system computer,
52 Monitor of control system computer
53 Interface of control system computer,
59 Control unit of objective lens,
61 First imaging lens,
62 Second imaging lens,
63 Third imaging lens,
64 Fourth imaging lens,
66 Control unit of fourth imaging lens,
67 Control unit of third imaging lens,
68 Control unit of second imaging lens
69 Control unit of first imaging lens,
71 Image plane of specimen by objective lens,
72 Image plane of specimen by first imaging lens,
76 Image display,
77 Image recording and arithmetic processing unit,
78 Control unit of image observation and recording medium,
79 Image observation and recording medium,
8 Interference fringes,
81 First deflector,
82 Second deflector,
83 Deflection point by first deflector,
835 Plane that includes the deflection point 83 and is perpendicular to optical axis,
84 Deflection point by second deflector,
845 Plane that includes the deflection point 84 and is perpendicular to the optical axis,
85 Deflection point by electron biprism,
855 Plane that includes the deflection point 85 and is perpendicular to optical axis,
86 Synthesized deflection point by first deflector and second deflector,
865 Plane that includes the deflection point 86 and is perpendicular to optical axis,
88 Interferogram,
89 Observation and recording plane,
9 Filament electrode of electron biprism,
91 First electron biprism,
93 Electron beam biprism device,
95 Second electron biprism,
96 Control unit of second electron biprism,
97 Control unit of two-stage deflectors,
98 Control unit of first electron biprism, and
99 Parallel plate grounded electrode.

1. An electron beam biprism device that is used in a transmission electron microscope or an electron beam device for performing energy analysis of an electron beam having passed through a specimen, comprising:
an electron biprism for splitting and deflecting the electron beam that propagates in a direction from an electron source to an observation or recording device on an optical axis along the optical axis of the electron microscope or the electron beam device; and
at least two deflectors for giving a deflection action to the electron beam independently from the electron biprism on electrooptically the same plane that includes deflection planes of the electron beams determined by the electron biprism and the optical axis.

2. The electron beam biprism device according to claim 1,
wherein the electron biprism and the deflectors comprise the electron biprism, a first deflector, and a second deflector in an order of a direction in which the electron beam propagates.

3. The electron beam biprism device according to claim 1,
wherein the electron biprism and the deflectors comprise a first deflector, the electron biprism, and a second deflector in an order of direction in which the electron beam propagates.

4. The electron beam biprism device according to claim 1,
wherein the electron biprism and the deflectors comprise a first deflector, a second deflector, and the electron biprism in an order of direction in which the electron beam propagates.

5. The electron beam biprism device according to claim 1,
wherein by a deflection angle that the first deflector gives to the electron beam and a deflection angle that the second deflector gives to the electron beam being adjusted, respectively, a deflection position on the optical axis that the electron biprism gives to the electron beam and a corresponding deflection position on the optical axis of the electron beam after it is emitted from the second deflector are in agreement.

6. The electron beam biprism device according to claim 1,
wherein when defining the optical axis as an axis in the deflection plane of the electron beam including the optical axis, setting a z-axis with a deflection point that the electron biprism gives to the electron beam being set to an origin, defining a travelling direction of the electron beam as a positive direction and defining a clockwise direction of the travelling direction of the electron beam in the deflection plane as a positive angle, designating a deflection angle that the first deflector gives to the electron beam as β₁ and designating a deflection angle that the second deflector gives to the electron beam as β₂, designating a coordinate of the deflection position of the first deflector on the z-axis as d₁, and designating a coordinate of the deflection position of the second deflector on the z-axis as d₂,
the deflection angles that the first deflector and the second deflector give to the electron beam, respectively, satisfy the following formula:
d₁×β₁×d₂×β₂=0.

7. The electron beam biprism device according to claim 1,
wherein at least one deflection action of the deflection action that the electron biprism gives to the electron beam, the deflection action that the first deflector gives to the electron beam, and the deflection action that the second deflector gives to the electron beam is one that is caused by an electric field.

8. The electron beam biprism device according to claim 1,
wherein at least one deflection action of the deflection action that the electron biprism gives to the electron beam, the deflection action that the first deflector gives to the electron beam, and the deflection action that the second deflector gives to the electron beam is one that is caused by a magnetic field.

9. The electron beam biprism device according to claim 1,
wherein the electron biprism, the first deflector for giving the deflection action to the electron beam, and the second deflector for giving the deflection action to the electron beam are movable, as one body, in an arbitrary direction perpendicular to the optical axis, and are pivotable, as one body, about an axis parallel to the optical axis as a center, and
wherein insertion of the electron biprism, the first deflector, and the second deflector onto an optical path of the electron beam and extraction thereof from the optical path of the electron beam are made as one body.

10. An electron beam device that comprises:
a source of an electron beam;
a condenser optical system for illuminating the electron beam emitted from the source on a specimen,
a specimen holding device for holding the specimen on which the electron beam illuminates,
an imaging lens system including an object lens for imaging an image of the specimen, and
an device for observing or recording the specimen image,
wherein an electron beam biprism device is placed at an image plane position of the specimen posterior to one or a plurality of lenses belonging to the imaging lens system located downstream of a position at which the specimen is placed on an optical axis of the electron beam in a travel direction of the electron beam, and
wherein a second electron biprism is placed in downstream of the electron beam biprism device on the optical axis of the electron beam in a travel direction of the electron beam.

11. The electron beam device according to claim 10,
wherein the electron beam biprism device is comprised of:
a first electron biprism for splitting and deflecting the electron beam that propagates along the optical axis of the electron beam device in a direction from the source to the device for observing or recording it on the optical axis; and
at least two deflectors each for giving a deflection action to the electron beam independently from the electron biprism on electrooptically the same plane that includes a deflection plane of the electron beam determined by the electron biprism and the optical axis.

12. The electron beam device according to claim 10,
wherein the second electron biprism is located in a space of the shade of the electron beam made by the electron beam biprism device.

13. The electron beam device according to claim 10,
wherein the electron biprism and the deflectors are comprised of the electron biprism, a first deflector, and a second deflector in an order of direction in which the electron beam propagates.

14. The electron beam device according to claim 10,
wherein at least one deflection action of the deflection action that the electron biprism gives to the electron beam, the deflection action that the first deflector gives to the electron beam, and the deflection action that the second deflector gives to the electron beam is one that is caused by an electric field.

15. The electron biprism according to claim 10,
wherein the electron biprism, the first deflector for giving a deflection effect to the electron beam, and the second deflector for giving a deflection effect to the electron beam are movable as one body in an arbitrary direction perpendicular to the optical axis, and are pivotable as one body about an axis parallel to the optical axis, and
wherein insertion of the electron biprism, the first deflector, and the second deflector onto an optical path of the electron beam and extraction thereof from the optical axis of the electron beam are made as one body.
